(19) United States
(12) Patent Application Publication
(10) Pub. No.: US 2015/0062803 A1
(43) Pub. Date: Mar. 5, 2015

(54) SERVER

(71) Applicants: INVENTEC CORPORATION, Taipei (TW); Inventec (Pudong) Technology Corporation, Shanghai (CN)

(72) Inventors: Mao-Ching LIN, Taipei (TW); Kuo-Chin HUANG, Taipei (TW)

(73) Assignees: INVENTEC CORPORATION, Taipei (TW); Inventec (Pudong) Technology Corporation, Shanghai (CN)

(21) Appl. No.: 14/052,417

(22) Filed: Oct. 11, 2013

(30) Foreign Application Priority Data
Aug. 28, 2013 (CN) 201310382710.0

(51) Int. Cl. H05K 7/20

(52) U.S. Cl. CPC H05K 7/20727; H05K 7/20772
USPC 361/679.47

(57) ABSTRACT

A server includes a motherboard and a heat dissipation module. The motherboard includes a heat source. The heat dissipation module includes a cooling plate, a liquid cooling heat exchanger, a circulation line and several fans. The cooling plate is thermally contacted with the heat source. The liquid cooling heat exchanger is located on one side of the motherboard. The liquid cooling heat exchanger is connected with the cooling plate via the circulation line for forming a circulation circuit. The plurality of fans are located next to the liquid cooling heat exchanger.

### CROSS-REFERENCE TO RELATED APPLICATIONS

This non-provisional application claims priority under 35 U.S.C. §119(a) on Patent Application No(s). 201310382710.0 filed in China on Aug. 28, 2013, the entire contents of which are hereby incorporated by reference.

### TECHNICAL FIELD

The disclosure relates to a server, more particularly to a server having a heat dissipation module.

### BACKGROUND

With the development of the technology, electrical device has been widely used nowadays. Moreover, engineers are devoted to the development of the electrical device in its efficiency and performance. Specifically, the operating speed of the electrical device becomes increasingly faster and the performance is better than before, which meets people's expectations of the electrical device. For example, a server comprises multiple electrical components such as several central processing units, several storage devices, or several interface cards. Therefore, the operating speed of a server is increased by means of disposing more electrical components, expanding the storage capacity as well as improving the performance of the server.

However, when the operating speed of the electrical device is getting faster or the number of the electrical devices is increased, the rising heat of the electrical devices is accompanied with the operating speed or the increase of the electrical device. Thus, the temperature of the electrical component is getting higher, accordingly affecting the normal operation of the server. In order to solve the above-mentioned problem, the server generally includes a plurality of fan modules for performing a thermal exchange by increasing the speed of thermal convection within the server, which accordingly decreases the temperature of the server. The fans having larger size and greater power, or more fans are adopted in the prior art, in order to enhance heat dissipation and accordingly decrease the temperature of electrical component. Nevertheless, when people utilize more fans or larger fans with high power, those fans occupy some part of interior spaces originally belonged to electrical components and generate more noises. Therefore, there is a need to design a server including a heat dissipation module having less volume and better performance.

### SUMMARY

An embodiment of the disclosure provides a server comprising a motherboard and a heat dissipation module. The motherboard includes a heat source. The heat dissipation module includes a cooling plate, a liquid cooling heat exchanger, a circulation line and a plurality of fans. The cooling plate is thermally contacted with the heat source. The liquid cooling heat exchanger is located on one side of the motherboard. The liquid cooling heat exchanger is connected with the cooling plate via the circulation line for forming a circulation circuit. The plurality of fans are located next to the liquid cooling heat exchanger.

### BRIEF DESCRIPTION OF THE DRAWING

The disclosure will become more fully understood from the detailed description given herein below and the drawing are for illustration only, and thus does not limit the present disclosure, wherein:

FIG. 1 is a top-view of a server according to an embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

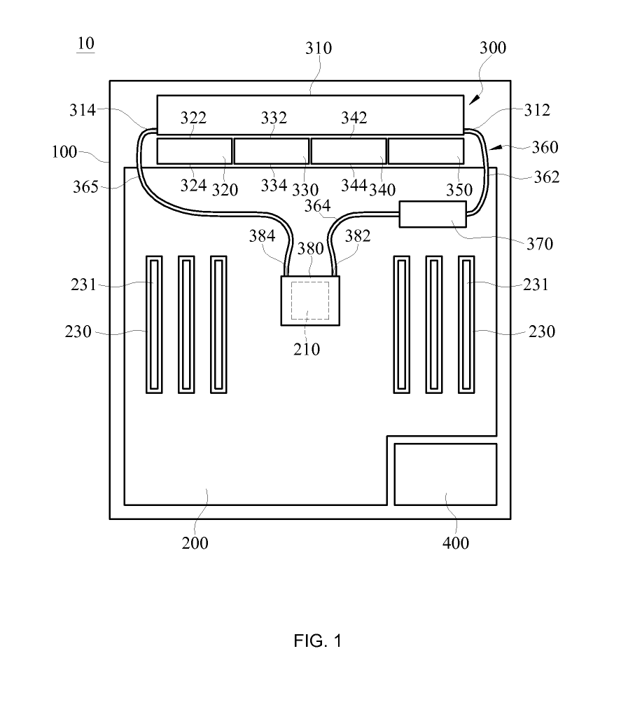

Please refer to the FIG. 1, which is a top view of a server according to an embodiment of the disclosure. A server 10 comprises a housing 100, a motherboard 200, a heat dissipation module 300 and a power supply 400.

In this embodiment, the motherboard 200 is located inside the housing 100. The motherboard 200 comprises a heat source 210, a plurality of slots 230 and a plurality of interface cards 231. In this embodiment, the heat source 210 is a central processing unit but the disclosure is not limited thereto. In some embodiments of the disclosure, the heat source 210 is a chip, a storage device or a power supply. The number of heat sources is plural and both of them are separated by a distance. The heat source 210 generates thermal energy when the server 10 operates. In this embodiment, the slots 230 are located on the two sides of the heat source 210, respectively. The interface card 231 is located on the slot 230 and the interface card 231 generates thermal energy as well when the server 10 operates.

In this embodiment, the heat dissipation module 300 is located inside the housing 100, but the location of the heat dissipation module 300 is not limited to the disclosure. The heat dissipation module 300 comprises a cooling plate 380, a liquid cooling heat exchanger 310, a circulation line 360 and a plurality of fans 320, 330, 340 and 350. The cooling plate 380 is in thermal contact with the heat source 210. The cooling plate 380 includes a chamber (not shown) and a heat sink set (not shown) located on the chamber. The liquid cooling heat exchanger 310 is located on one side of the motherboard 200. A plurality of fans 320, 330, 340 and 350 are located next to the liquid cooling heat exchanger 310. The liquid cooling heat exchanger 310 is connected with the cooling plate 380 via the circulation line 360. Therefore, a circulation circuit is formed by the circulation line 360, the liquid cooling heat exchanger 310 and the cooling plate 380. The heat of the cooling plate 380 is transferred to the liquid cooling heat exchanger 310 by a liquid flowing in the circulation circuit. It is noted that the number and the location of the liquid cooling heat exchanger 310 and the fans 320, 330, 340 and 350 are not limited to the disclosure. In some embodiments of the disclosure, the liquid cooling heat exchanger 310 and the fans 320, 330, 340 and 350 are located outside the housing 100. Moreover, the number of fans 320, 330, 340 and 350 is not limited to singular one.

The following describes the detailed locations of the fans. In this embodiment, the fans 320, 330, 340 and 350 are located between the liquid cooling heat exchanger 310, and the cooling plate 380 and the fans 320, 330, 340 and 350 are arranged side by side. For example, each of the fans 320, 330, 340 and 350 includes a fan inlet 322,332,342 and a fan outlet 324,334,344, respectively, and all of the fan inlet 322,332,342 face toward the liquid cooling heat exchanger 310. Two of the fan outlets 334,344 face toward the heat source 210 whereas another fan outlet 324 faces toward the slot 230. In this embodiment, the total width of the liquid cooling heat exchanger 310 is substantially equal to the overall width accumulated by 320, 330, 340 and 350. Therefore, the rotation of fans 320, 330, 340 and 350 drives the liquid cooling heat exchanger 310 to perform thermal exchange with the outside air.

In some embodiments of the disclosure, the heat dissipation module 300 further comprises at least an air duct hood (not shown) which are located on the fan inlet 322,332,342 or fan outlet 324,334,344 of the fans, respectively. The outside air is effectively guided into the fans 320,330,340 when the air duct hood is located on the fan inlets 322,332,342 of the fans 320,330,340. Therefore, the air duct hood guides the airflow generated by the fans 320,330,340 to increase the heat dissipation efficiency.

In this embodiment, the heat dissipation module 300 further comprises a water pump 370 which is located in the circulation line 360. The liquid cooling heat exchanger 310 includes a liquid inlet 314 and a liquid outlet 312. Moreover, the cooling plate 380 includes an entry port 382 and an exit port 384, wherein the entry port 382 and the exit port 384 are connected with the two sides of the chamber of the cooling plate 380, respectively. The circulation line 360 comprises a first circulation pipe 362, a second circulation pipe 364 and a third circulation pipe 365. Firstly, one end of the first circulation pipe 362 is connected with the liquid outlet 312 of the liquid cooling heat exchanger 310 and the other end of the first circulation pipe 362 is connected with one end of the water pump 370. Secondly, one end of the second circulation pipe 364 is connected with the other end of the water pump 370 and the other end of the second circulation pipe 364 is connected with the entry port 382 of the cooling plate 380. Lastly, one end of the third circulation pipe 365 is connected with the exit port 384 of the cooling plate 380 and the other end of the third circulation pipe 365 is connected with the liquid inlet 314 of the liquid cooling heat exchanger 310. Namely, in this embodiment, the liquid outlet 312 of the liquid cooling heat exchanger 310 is connected with the entry port 382 of the cooling plate 380 via the water pump 370.

The power supply 400 is located on the other side of the motherboard 200, which is opposite to the side having liquid cooling heat exchanger 310. The number and the location of the power supply 400 are adjusted according to the actual requirement.

The following is the heat dissipating process from the heat dissipation module 300. Firstly, the heat is generated from the heat source 210, the interface card 231, the power supply 400 and the motherboard 200 when the server 10 operates. The liquid with lower temperature on the liquid outlet 312 inside the liquid cooling heat exchanger 310 is extracted by the water pump 370 and flows toward the water pump 370 via the first circulation pipe 362. Next, the liquid orderly passes through the second circulation pipe 364 and the entry port 382 of the cooling plate 380 and then enters the cooling plate 380. Moreover, the heat source 210 is in thermal contact with the cooling plate 380 and the heat generated by the heat source 210 is transferred to the cooling plate 380. Then, the cooling plate 380 performs thermal exchange with the heat from the heat source 210. Therefore, the heat is transferred to the liquid and the temperature of the liquid is increased because the liquid absorbs the heat released from the heat source 210. Afterward, the liquid with high temperature on the exit port 384 of the cooling plate 380 flows toward the liquid inlet 314 of the liquid cooling heat exchanger 310 via the third circulation pipe 365. Finally, the heat of the liquid with high temperature is transferred to the liquid cooling heat exchanger 310 and the liquid cooling heat exchanger 310 performs thermal exchange with the outside air for taking heat out of the server 10, which decreases the temperature of the liquid. In addition, the rotation of fans 320, 330, 340 and 350 speeds up the thermal convection with outside air. Simultaneously, the outside air is guided into the server 10 by the fans 320, 330, 340 and 350 to perform thermal exchange with the heat source 210, the interface card 231, the power supply 400 and other electrical components on the motherboard 200 for removing the heat. By doing so, the temperature of the whole server 10 rapidly decreases, which further maintains the stable operation of the server 10. After the temperature of the liquid inside the liquid cooling heat exchanger 310 decreases, the liquid flows from the liquid cooling heat exchanger 310 for performing the thermal exchange with the cooling plate 380.

As a whole, the heat source 210 is the main heat source of the server 10, thus, the temperature of the server 10 rapidly decreases for maintaining stable operation after the heat of the heat source 210 is removed by the heat dissipation module 300. Even the airflow into the server 10 guided by the fans 320, 330, 340 and 350 has absorbed the heat from the liquid cooling heat exchanger 310, the airflow inside the server 10 does not affect the thermal exchange with other electrical components.

In addition, compared with the prior art where more fans or fans with high power are adopted (e.g., model: 4056), fewer fans or fans with lower power are adopted by the heat dissipation modules 300 of the server 10 (e.g., model: 4028) in this embodiment of the disclosure, so that the heat dissipation efficiency of the server 10 is effectively raised. Therefore, the server 10 accommodates more electrical components or central processing units for improving the performance and the operating speed of the server.

According to the embodiment of the server, the heat generated from the heat source is transferred to the liquid cooling heat exchanger via the cooling plate and the rotating fans enhance the thermal exchange speed of the liquid cooling heat exchanger with outside air. Therefore, compared with the prior art, the temperature of the heat source is significantly decreased and the heat dissipating efficiency is significantly increased, so the embodiment of the disclosure solves the problem of poor heat dissipation. Furthermore, the server in this embodiment decreases the number of the fans and the volume of fans but increases the heat dissipating efficiency for energy saving as well.

What is claimed is:

1. A server, comprising:
a motherboard having a heat source; and
a heat dissipation module, comprising:
a cooling plate thermally contacted with the heat source;
a liquid cooling heat exchanger located on one side of the motherboard;
a circulation line, wherein the liquid cooling heat exchanger is connected with the cooling plate via the circulation line for forming a circulation circuit; and
a plurality of fans located next to the liquid cooling heat exchanger.

2. The server according to claim 1, wherein the heat source is a central processing unit.

3. The server according to claim 1, wherein the plurality of fans are located between the liquid cooling heat exchanger and the cooling plate.

4. The server according to claim 3, wherein the plurality of fans are arranged side by side.

5. The server according to claim 1, wherein each of the plurality of fans has a fan inlet facing toward the liquid cooling heat exchanger.

6. The server according to claim 1, wherein each of the plurality of fans has a fan outlet and at least one of the fan outlets faces toward the heat source.

7. The server according to claim 1, wherein the heat dissipation module further comprises a water pump which is located in the circulation circuit.

8. The server according to claim 7, wherein the liquid cooling heat exchanger includes a liquid outlet and the cooling plate includes an entry port, wherein the liquid outlet of the liquid cooling heat exchanger is connected with the entry port of the cooling plate via the water pump.
